(19) United States
(12) Patent Application Publication
(10) Pub. No.: US 2020/0313577 A1
(43) Pub. Date: Oct. 1, 2020

(54) Methods For Parallel Electrostatic Pickup

(71) Applicant: The Trustees of Columbia University in the City of New York, New York, NY (US)

(72) Inventors: Joni Mici, New York, NY (US); Jared D. West, Watseka, IL (US); Jeffrey Frederick Jaquith, New York, NY (US); Hod Lipson, New York, NY (US)

(21) Appl. No.: 16/829,482

(22) Filed: Mar. 25, 2020

Related U.S. Application Data
(60) Provisional application No. 62/823,070, filed on Mar. 25, 2019.

(51) Int. Cl. H02N 13/00; H01L 21/683

(52) U.S. Cl. CPC H02N 13/00; H01L 21/6833

(57) ABSTRACT

Provided are layered assembly systems and methods. The systems can include one or more electroadhesive elements, an electroadhesive element comprising a first electrode and a second electrode, an electroadhesive element being configured to effect electroadhesion between the electroadhesive element and an object, and the electroadhesion of one or more of the one or more electroadhesive elements optionally being independently controllable. The systems can be utilized to performed layered assembly of larger objects, and can do so in a self-correcting manner by repositioning or even removing nonconforming objects from the assembly. The disclosed systems can also be used as sensors to determine an electrical characteristic of one or more objects positioned proximate to one or more of the electroadhesion elements of the positioner system.

### RELATED APPLICATIONS

The present matter claims priority to and the benefit of U.S. patent application No. 62/823,070, “Methods for Parallel Electrostatic Pickup” (filed Mar. 25, 2019), the entirety of which application is incorporated herein by reference for any and all purposes.

### TECHNICAL FIELD

The present disclosure relates to the field of layered assembly and to the field of electrostatic pickup systems.

### BACKGROUND

Existing additive manufacturing (AM) processes currently in use are unsuitable for fabrication of dissimilar materials in the same build process. While progress has been made in multi-polymer AM, and multi-metal AM, material chemistry fundamentally prevents established AM processes, e.g., PolyJet, Powder Bed Fusion, and Directed Energy Deposition, from co-fabricating parts comprised of metals and polymers in the same build tray. To highlight these material science limitations, consider that some of the most advanced 3D printers can manufacture FAA-qualified fuel nozzles, yet cannot fabricate a handheld TV remote.

One way to broadly address this multi-material challenge is to fine tune the properties of dissimilar materials to allow their co-fabrication using established AM processes, such as those based on material extrusion. This approach was examined by Malone et al., who focused on its utility in the freeform fabrication of batteries and conductive wiring in assemblies using a single FDM-like process. More recently, Muth et al. demonstrated the capability of printing strain sensors in soft elastomers using an FDM-like process.

While these approaches present some evidence of success, these approaches also suffer from two fundamental limitations. First, sought-after material properties, such as high conductivity and stiffness, are often compromised to achieve in-printer compatibility. Second, as the resolution of most multi-material AM processes is still relatively low, only relatively crude structures, such as circuit interconnects, can be manufactured. Owing to these issues, printing functional electro-mechanical systems remains a challenge. Accordingly, there is a long-felt need in the art for additive manufacturing systems that can provide multimaterial products in an efficient fashion.

### SUMMARY

In meeting the described long-felt needs, the present disclosure first provides positioner systems, comprising: one or more (e.g., a plurality of) electroadhesive elements, an electroadhesive element comprising a first electrode and a second electrode, an electroadhesive element being configured to effect electroadhesion between the electroadhesive element and an object, and the electroadhesion of one or more of the one or more electroadhesive elements optionally being independently controllable.

The present disclosure also provides methods, the methods comprising: with a positioner system according to the present disclosure, effecting layered assembly by way of electroadhering one or more objects to one or more electroadhesion elements.

Further provided are methods, comprising: with one or more electroadhesive elements, the one or more electroadhesive elements optionally being arranged in an array; effecting electroadhesion between at least of the one electroadhesive elements and at least one object placed at an original location; and effecting relative motion between the object and the original location.

Additionally provided are methods, comprising: with a positioner system according to the present disclosure, determining an electrical characteristic of one or more objects positioned proximate to one or more of the electroadhesion elements of the positioner system.

### BRIEF DESCRIPTION OF THE DRAWINGS

The file of this patent or application contains at least one drawing/photograph executed in color. Copies of this patent or patent application publication with color drawing(s)/photograph(s) will be provided by the Office upon request and payment of the necessary fee.

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1 provides layered assembly concepts, showing (upper image) an illustration of a crawling robot and (lower panel) a smartphone, both comprising of millions of building blocks from a small repertoire of functional types, namely structural, electrical, light emitting, and actuating.

FIG. 2 provides an exemplary image of a layered assembly (LA) system equipped with a 32×32 electrode array selectively gripping a circular shape out of an array of objects;

FIG. 3A provides a view of an exemplary electroadhesive gripper (for a dielectric object, the dielectric layer can be removed), and FIG. 3B provides a view of an alternative embodiment in which the gripper includes two dielectric regions (e.g., two regions of different materials, two regions of the same material in which one of the regions has a different dielectric strength than the other region);

FIGS. 4A-4F provides various electrode designs, including (FIG. 4A) an interdigitated spiral design with 0.010″ spacing, (FIG. 4B) a “squiggly” comb with 0.010″ trace spacing, (FIG. 4C) an interdigitated spiral design with 0.010″ spacing, and filled in background, (FIG. 4D) a chevron-shaped comb design with 0.010″ spacing, (FIG. 4E) a comb electrode design with 0.010″ trace spacing, and (FIG. 4F) a comb electrode design with 0.006″ spacing;

FIGS. 5A-5B provide exemplary CAD renderings of (FIG. 5B) a spiral electrode array, and (FIG. 5A) a comb electrode array; both electrodes have 0.010″ spacing between the leads;

FIGS. 6A-6F provide (with FIG. 6A corresponding to FIG. 4A, FIG. 6B corresponding to FIG. 4B, FIG. 6C corresponding to FIG. 4C, FIG. 6D corresponding to FIG. 4D, FIG. 6E corresponding to FIG. 4E, and FIG. 6F corresponding to FIG. 4F) COMSOL simulations of electrostatic fields corresponding to FIGS. 4A-4F;

FIGS. 7A-7D provide COMSOL Simulation results of electrode arrays—(FIG. 7A) normalized electric field plot of 2×2 spiral electrode array, (FIG. 7B) plot of normalized electric field for spiral electrodes at x=0.485 mm cross section, (FIG. 7C) normalized electric field plot of 2×2 comb electrode array, and (FIG. 7D) a plot of normalized electric field for comb electrodes at x=0.485 mm cross section.

FIGS. 8A-8C provide, variously, an example of a manufactured (FIG. 8A) 2×2 spiral electrode array, and (FIG. 8B) 2×2 a comb electrode array, and (FIG. 8C) metallic, metal-topped, and polymeric objects, from left to right;

FIGS. 9A-9C provide, variously, (FIG. 9A) an exemplary testing setup, magnifying the alignment jig, (FIG. 9B) a close-up view of an as-manufactured spiral electrode, and (FIG. 9C) a spiral electrode shorting at a point of high curvature;

FIGS. 10A-10B provide, variously, views of objects in a testing setup—(FIG. 10A) four objects placed in the alignment jig, awaiting pickup, and (FIG. 10B) following contact, the electrode array selectively picks up two of the four objects on the jig.

FIGS. 11A-11C provide, variously, (FIG. 11A) an analysis of the gripping reliability of a bare electrode when applied to polymeric objects, (FIG. 11B) an analysis of the gripping reliability of a Teflon™-coated electrode array when used to collect polymeric objects with copper tops, and (FIG. 11C) an analysis of gripping reliability of a Teflon™-coated electrode array when attempting to collect Al objects.

FIGS. 12A-12F provide an exemplary fabrication process: (FIG. 12A) The beginning of the processes: an empty tray in pink, and a blue deposition head, (FIG. 12B) completed placement of first batch of objects, (FIG. 12C) completed placement of second batch of objects, (FIG. 12D) completed placement of third batch of objects, (FIG. 12E) extraneous object is noticed and removed, (FIG. 12F) final discretized “C”.

FIGS. 13A-13H provide an exemplary fabrication process (FIG. 13A) beginning of the grasping process for SMT resistors (as objects), (FIG. 13B) showing an electrode array lowered to contact resistors' surfaces, (FIG. 13C) showing that the electrode array selectively grips intended resistors, (FIG. 13D) showing the voltage turned off and the resistors drop, (FIG. 13E) beginning of the grasping process for polymer objects, (FIG. 13F) the electrode array is lowered to contact object surfaces, (FIG. 13G) the electrode array selectively grips intended objects, and (FIG. 13H) the voltage is turned off and polymer objects drop.

FIGS. 14A-14E provide screenshots from a video recording showing electrostatic pickup of aluminum objects.

FIG. 15A provides an image of checkerboarded 4×4 array module with comb-shaped electrode (covered with solder mask), and FIG. 15B provides a view of a checkerboarded 4×4 array module with square-spiral-shaped electrodes, which module is not covered with solder mask. (It should be understood that the disclosed technology is not limited to checkerboarded arrangements, and that adjacent electrodes can be positioned such that they fill the entirety of the surface of an electroadhesive element.)

FIG. 16A provides a top-down view of an exemplary arrangement of electroadhesive elements with their respective control boards, and FIG. 16B provides a bottom-up view of that exemplary arrangements.

### DETAILED DESCRIPTION OF ILLUSTRATIVE EMBODIMENTS

The present disclosure may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable, and it should be understood that steps can be performed in any order.

It is to be appreciated that certain features of the invention which are, for clarity, described herein in the context of separate embodiments, can also be provided in combination in a single embodiment. Conversely, various features of the invention that are, for brevity, described in the context of a single embodiment, can also be provided separately or in any subcombination. All documents cited herein are incorporated herein in their entireties for any and all purposes.

Further, reference to values stated in ranges include each and every value within that range. In addition, the term “comprising” should be understood as having its standard, open-ended meaning, but also as encompassing “consisting” as well. For example, a device that comprises Part A and Part B can include parts in addition to Part A and Part B, but can also be formed only from Part A and Part B.

Overview

As explained elsewhere herein, successful multi-material printing is needed for production of smart structures containing sensors, actuators, and microprocessors, as well as power and logic components. These drawbacks are overcome by the disclosed additive manufacturing technology, which can be employed in the fabrication of even the most complex components requiring optimized nanofabrication processes. Provided here is a Layered Assembly (LA) approach that broadly addresses the multi-material limitations of current additive manufacturing approaches.

Layered Assembly (LA) is an additive manufacturing method that systematically builds multi-material parts through layer-by-layer deposition of 3D building blocks known as “objects” (also termed “voxels,” in some instances). By using objects in place of the raw material, LA fundamentally differs from established AM processes in how the raw material is shaped, manufactured, assembled, and ultimately thought about in design paradigms. The discrete and digital nature of the objects used in LA contrast starkly with the continuous filament, resin, or powder melt pools used in established AM processes. Further, LA differs from existing multi-material AM methods in that LA enables the co-fabrication of parts comprised of both metals and polymers in the same build tray.

Owing to their relatively small scale, objects can be assembled into a wide range of geometries to produce recyclable and modular electromechanical components, which in turn comprise a complex, multi-material product. In LA, objects serve as feedstock, replacing the traditional raw materials in the manufacturing process. Because individual objects are independent of the final product characteristics, they can be equipped with microprocessors or batteries, extending their functionality beyond what is associated with their intrinsic material properties. Moreover, objects can be reused, making LA a more cost-effective process and paving the way toward sustainable manufacturing.

Each type of object used in the LA process can be mass-produced separately by traditional optimized methods. When fabricating multi-material products, objects of required design and functionality are assembled akin to building blocks using a pick-and-place approach to produce multi-material systems of virtually unbounded complexity. Such object-based structures have been termed “digital materials” by industry practitioners and academic researchers.

Table 1 provides some relationships between different object types and the design space afforded by their use. As the number of distinct types of objects expands, the design scope grows exponentially. As demonstrated in nature, even a small range of distinct building blocks can give rise to a virtually unlimited number of unique designs, as only 22 amino acids were sufficient for the emergence of the immense diversity of biological life on Earth. Once the goal of harmoniously assembling multi-material structures has been attained, printing fully functioning systems, such as robots, will be possible, thus bringing AM to its logical conclusion.

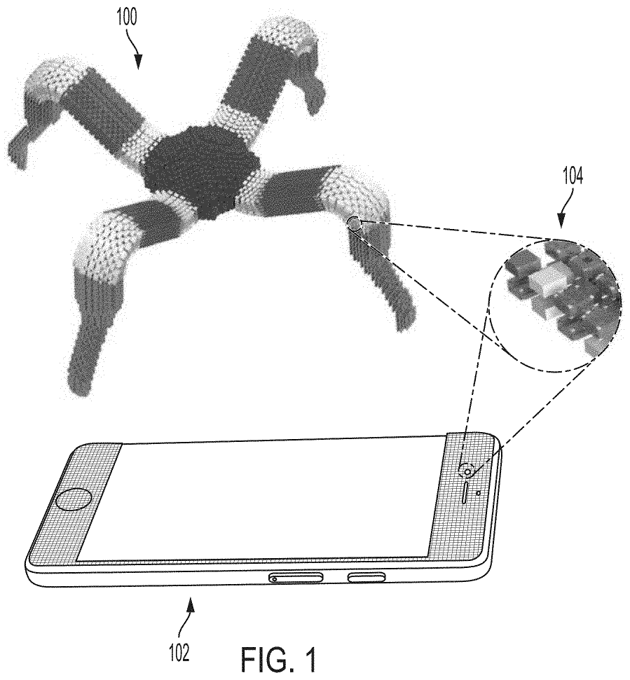

Two examples of fully functioning electromechanical systems are shown in FIG. 1, where a relatively small number of object types is employed to produce vastly different objects, in this case a smartphone (102), and an insect-like walking robot (100)—both comprised of over one million objects. As shown by close-up 104, each of smartphone 102 and walking robot 100 are comprised of many smaller component objects.

TABLE 1
Different object types and the design spaces they enable.

| Object Type | Design Space |
|---|---|
| Structural + Support objects | Arbitrary geometries |
| +Soft objects | Graded materials |
| +Conductor objects | 3D Interconnect |
| +Resistors, transistors, capacitors | Analog 3D circuits |
| +Batteries and PV objects | Power handling |
| +CPU/FPGA objects | Embedded intelligence |
| +Sensor, actuator objects | Fully operational robots |

Another benefit of LA is the ability to make objects using self-alignment, as this enables constructing objects that are more precise than the machine that built them. The important consequence of this paradigm shift is that the burden of precision is no longer on the machine, but rather the feedstock, which is easier to control. The self-alignment concept is exemplified by the LEGO™ brick design, which ensures that all individual components are compatible and can be used to build an infinitely large number of complex structures of much higher precision than that characterizing the hand that built them. As but one example of this approach, a given object can be configured (e.g., via the inclusion of a magnetic region, or the inclusion of a feature that is complementary to a feature on another object) so as to self-align with other objects.

In LA, resolution can be improved by reducing object size and increasing object count, which can only be achieved by parallel object placement to maintain speed when the process is scaled-up. For example, a million-object-class assembly would require twelve days to assemble on existing pick-and-place systems, such as the M2-iA™ robot made by FANUC America Incorporated. Thus, without improvement to process scalability, a billion-object assembly would take nearly a year, as the total assembly time using a serial pick-and-place process increases linearly with object count. This example aptly illustrates the necessity of a parallel process that can considerably shorten the manufacturing time.

The disclosed LA process addresses this issue effectively, as the time required for assembly increases as the cube root of the number of objects required. Moreover, optimizing the use of parallel arrays allows LA to scale with the number of layers, rather than the number of objects, which is highly beneficial, given that the difference between linear and cube root scalability grows rapidly with the increase in the number of objects required for assembly.

In order to realize a highly parallel assembly process, the LA gripper arrays can be mechanically robust, scalable, and compatible in a wide variety of environments, including outer space, while requiring low power.

As an illustration, 2×2 arrays of electroadhesive grippers were designed in both comb- and spiral-shaped electrode geometries. Electrodes were nominally designed for grasping objects of 3×3 mm cross-section. Electrostatic field simulations were performed in COMSOL Multiphysics for both single electrodes, and 2×2 electrode arrays. The selective gripping capability of the electrode arrays was tested at voltages in the 75-800 V range and applied to both polymer and metallic objects. A comparison of object performance in terms of geometry revealed that comb-shaped objects were superior, with essentially 100% reliability when operating in the 600-800 V range.

Electroadhesion

Robotic grippers are typically classified as astrictive, ingressive, impactive, and continguitive. Astrictive processes, for example, require fields—which could be a pressure field (e.g., partial vacuum), electrostatic, or electromagnetic—to produce binding forces. Continguitive grippers, on the other hand, achieve prehension via thermal and chemical effects and thus require direct contact between the gripper and object surfaces. Impactive grippers achieve prehension by applying mechanical forces to the surface of the intended object. Finally, ingressive grippers permeate the surface of the target object to achieve prehension. At present, impactive and astrictive grippers are the most commonly used in the automation industry.

Because the gripping strength of astrictive methods is proportional to the surface area, such methods can be suited for gripping smaller parts, which inherently have higher surface area-to-mass ratios. Electroadhesion can be implemented with solid-state circuits. In addition, electroadhesion scales well to parallel arrays, and electroadhesion is also compatible with both conducting and non-conducting materials. Additionally, electroadhesion exhibits ultra-low power consumption and is compatible with the conditions in outer space. Electroadhesion is also well suited for use in vacuum, as electrodes are less susceptible to arcing, thus ensuring higher gripping strength. Batra et al. explored the possibility of in situ object construction beyond Earth's atmosphere, indicating that electroadhesive grippers can have a wide range of applications in vacuum.

Electroadhesion is the electrostatic effect of astriction that occurs between two surfaces subjected to an electric field. In the implementation described herein, electroadhesion occurs between an electroadhesive pad generating high electric field gradient and the separated charges in the target object. When plates with high positive and negative electric potential are in close proximity, a comparatively steep electric field gradient is generated. This field gradient causes any free electric charges in the vicinity to separate into positive and negative clusters. This in turn includes any object within that field, and thus the object and the electrodes themselves. Upon separation, negative charges in objects will be attracted by a positively charged electrode, and vice versa, creating an attraction force.

Various factors influencing process success have been identified ranging from intrinsic material properties (such as dielectric permittivity) to environmental factors (such as humidity and barometric pressure). Both conducting and non-conducting materials can be subject to electroadhesion, albeit based on different physics phenomena. In conductive materials, electroadhesive forces are generated mainly by electrostatic induction, while polarization is the source of electroadhesive forces in non-conductors. Parallel electroadhesive gripper arrays have not, to date, been developed or explored.

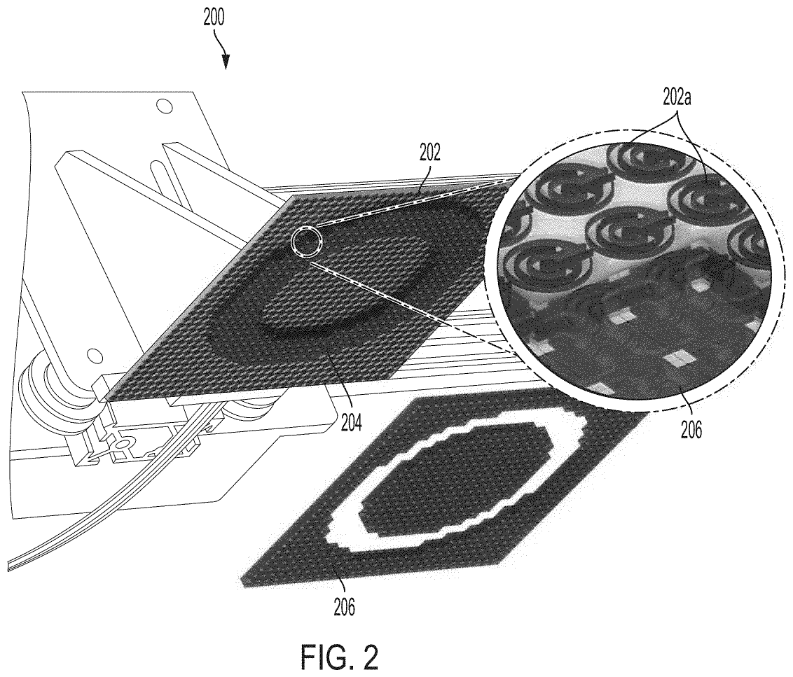

FIG. 2 shows an illustration of a 32×32 electrostatic gripping array system 200. As shown, system 200 can include a solid-state pick-and-place array 202. Array 202 can in turn engage with a supply of objects 206, and arrays 202 can then selectively adhere to specific objects (in this case, an O-shaped ring 204 of objects) from the supply of objects 206. As shown in the magnified view (right-hand side of FIG. 2), electrodes 202a can engage with objects from the supply of objects.

A pick-and-place array can be an N×N array, but can also be N×M array, or other shape, as an array need not be square or rectangular. An array can be circular in shape (i.e., comprising a plurality of electrodes tiled in a circular pattern), O-shaped, C-shaped, or triangular (or other polygon) in shape. An array can, of course, be N×N (or N×M) in configuration, with individual electrodes within the array being operated as appropriate to achieve the desired adhesion to objects, as an array can be constructed such that individual electrodes are individually addressable. As shown in FIG. 2, an O-shaped pattern of objects can be picked up from a supply of objects by operating an O-shaped subset of electrodes in an N×N array.

The electrodes can be arranged in a planar fashion such that the electrodes lie in a single plane, but this is not a requirement. An array can comprise two or more sets of electrodes, each set lying in a different plane. An array can also be disposed about a solid, e.g., around a cylinder that is rolled along a tray or other supply of objects to be picked up by the array. An array can be configured such that the electrodes lie along a curve, e.g., an array arranged in a 3-D hemispherical fashion. An array can be rigid in configuration, but can also be flexible (e.g., with a flexible jig, such as one made from an elastomer) such that the array can conform to a supply of objects to be picked up and/or to an object (or objects) being analyzed by the array.

As an example, an array can hold, e.g., 1024 objects of an arbitrary configuration. Extrapolating from this example, it is evident that a set of nine such arrays in a 3×3 configuration could assemble up to 9216 objects per layer. Assuming (solely for purposes of illustration) that one layer can be assembled per minute, 1 million objects can be placed within two hours.

Materials and Methods

Single Electrode Design

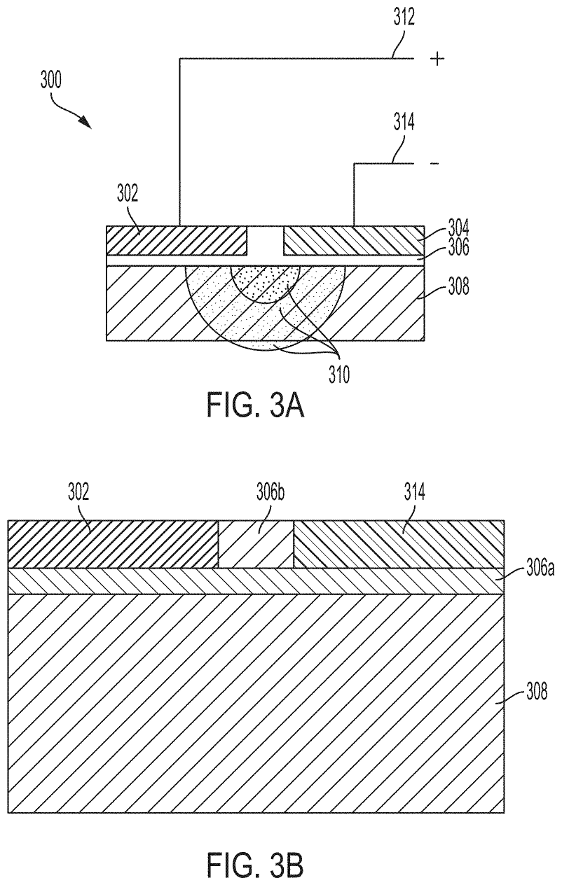

A cross-section of an exemplary electroadhesive gripper (also termed an “electroadhesive element,” in some locations) 300 is shown in FIG. 3A. As shown in that figure, an electroadhesive element 300 can include electrode leads (e.g., negative electrode lead 304 and positive electrode lead 302), which leads are connected, respectively, to a voltage supply (e.g., positive 312, negative 314).

Electroadhesive element 300 can further include dielectric 306, which dielectric can be superposed by leads 302 and 304 (or even contact one or both of leads 302 and 304). Operation of the electroadhesive element 300 gives rise to electric field 310, which electric field in turn effects electroadhesion between electroadhesive element 300 and object space 308 (the area occupied by the object to be picked up). The highest electric field density, which corresponds to the maximum electroadhesive strength, is attained in the gap between the positive and negative plates (302 and 304). As shown, an electroadhesive gripper can include a single dielectric material in which a region of the dielectric material is disposed between the (positive and negative) voltage leads 302 and 304. As an example, dielectric material 306 can be, e.g., soldermask material. Such a material has a dielectric constant of about 3.4 MV/m and a dielectric strength of about 39 MV/m.

As shown in FIG. 3B, electroadhesive gripper 300 can also include two regions of dielectric material, with a first region (306b) positioned between the (positive and negative) voltage leads 302 and 304, and a second region (306a) positioned between the leads and object 308. The first region 306b and the second region 306a can differ from one another in dielectric strength. As an example, the first region 306b can be formed of a first dielectric material, and the second region 306a can be formed of a second dielectric material. The first region and second region can be formed of the same material, with one of the two regions being doped or otherwise processed so as to exhibit a dielectric strength and/or dielectric constant that differs from the dielectric strength and/or dielectric constant of the other region. Alternatively, the first region and the second region can be formed of different materials.

Without being bound to any particular theory, one can maximize average electric field in the object space (the volume occupied by the object intended to be grasped). Adding a second dielectric material (as shown in, e.g., FIG. 3B) can enable an increased higher electric field in the object space, as such a second layer can mitigate dielectric breakdown (or arcing) between opposing electrodes as the voltage differential is raised. This higher electric field is confirmed in the simulation results in FIG. 17.

Without being bound to any particular theory, first dielectric material 306b can be a material that has a comparatively high dielectric strength, and the second dielectric material 306a can be a material that differs from the first dielectric material 306b. The first dielectric material 306a can be selected on the basis of its ability to effect application of a relatively strong field to the object being picked up. The second dielectric material can be a material that is relatively resistant to dielectric breakdown.

As an example, dielectric material 306a can be, e.g., Teflon™, which has a dielectric constant of about 2.1 MV/m and a dielectric strength of about 70 MV/m, and dielectric material 306b can be a neoprene coating, which material has a dielectric constant of about 6.7 MV/m, and a dielectric strength of about 26.7 MV/m.

One can include surface features (e.g., textures) in the surface of the dielectric materials and/or the electrodes. Surface texture can vary in pattern, and can be, e.g., spirals, pillars, ridges, troughs, points, mesas, waves, and the like. Textures can be imparted by micromachining, lithography, etching, abrasion, extrusion, grinding, and polishing, to name a few examples. Example surface textures are provided in Guo et al., J. Phys. D: Appl. Phys. 49 (2016) 035303. The surface roughness of can be, e.g., from about 1 to about 10 micrometers root mean square height. The surface roughness can also be, e.g., in excess of 5 micrometers.

One can also utilize composite dielectric materials. As an example, one can incorporate nanodiamonds into a polymeric dielectric material. Other materials that can be incorporated into the dielectric material include, without limitation, nanoparticles, carbon nanotubes (single- and multi-wall), graphene, graphite, nanoparticles (from about 1 to about 100 nm in cross-section) (metallic and otherwise), quantum dots, and the like.

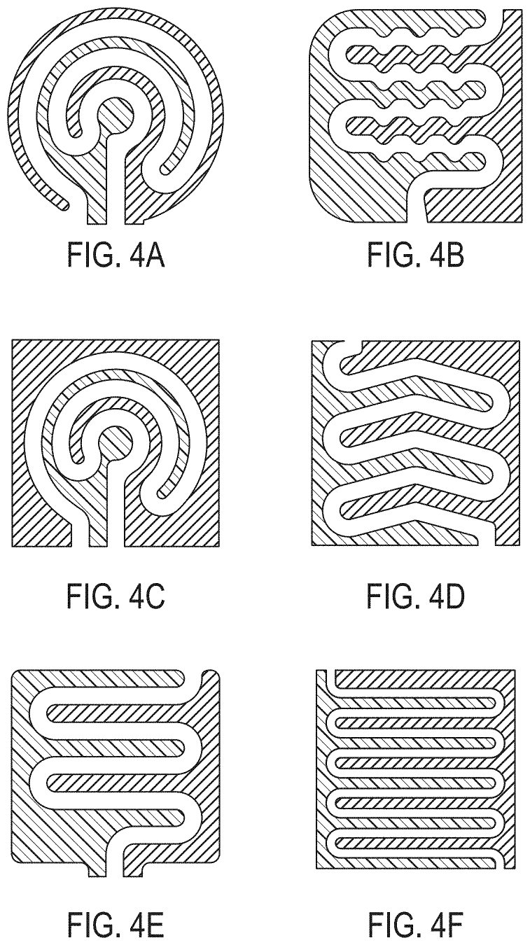

One can maximize average electric field throughout the object space, by changing electrode lead geometry, e.g., shape of the spacing between two leads, width of electrode leads, and the interdigitation gap (the distance between the positive lead and negative lead). A variety of interdigitated electrode geometries, are shown in FIGS. 4A-4F. As shown, FIG. 4A provides an interdigitated spiral design with a 0.010″ spacing. FIG. 4B provides what can be characterized as a “squiggly” comb design, having a 0.010″ trace spacing. FIG. 4C provides another alternative interdigitated spiral design, having a 0.010″ spacing with a filled in background. FIG. 4D provides a chevron-shaped comb design, with a 0.010″ spacing. FIG. 4E provides a further a comb electrode design with a 0.010″ spacing, and FIG. 4F provides a comb electrode design with 0.006″ spacing. An objective of electroadhesive gripper design is to maximize the electric field in the object space (FIG. 3B, element 308). A spiral electrode as shown in FIG. 4A may be optimal if we have a flexible electrode configuration, and a spiral electrode may provide more electric field in the object space than the embodiment in FIG. 4F, based on electrode deformation. Additionally, a spiral electrode may be used in place of a comb-shaped electrode if the intention is to grasp objects of a circular cross section. Finally, spiral electrodes may offer advantageous performance for grasping that requires high individual electrode addressability (wherein one seeks to minimize leakage of electric field from neighboring electrodes).

Without being bound to any particular theory, one can use a comparatively wide interdigitation gap when one desires to give rise to an electric field that penetrates comparatively deeply into the object space. This may be useful when one seeks to grip a relatively deep or tall object, or an object that has a comparatively rough surface. When one seeks to grip an object that is relatively thin, one can use a comparatively narrow interdigitation gap. The interdigitation gap can be, e.g., from about 0.002 to about 0.1 inches, or from about 0.003 to about 0.05 inches, or even from about 0.004 to about 0.01 inches.

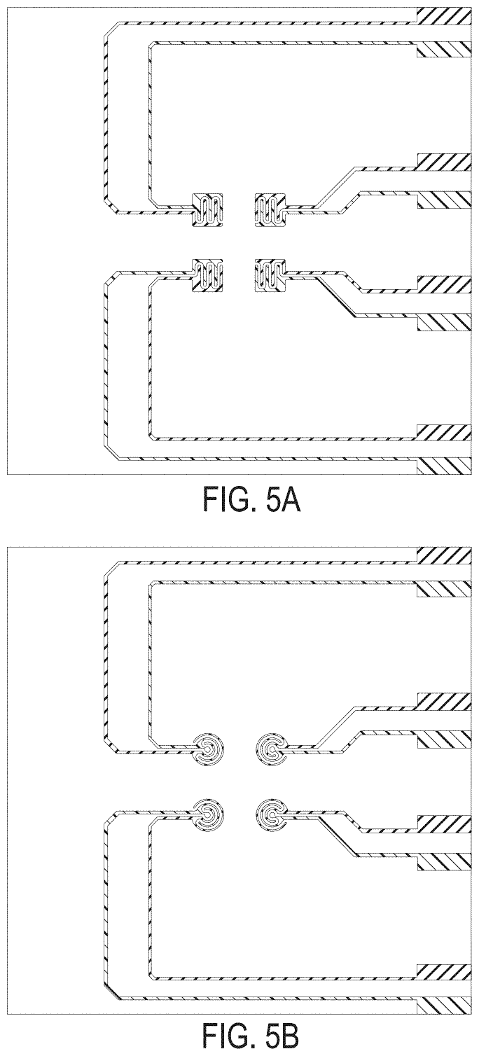

Electroadhesive grippers were designed for maximum interdigitation length, for traces bounded in a 3×3 mm design space. The machinable channel width was estimated at 0.010″. Renderings of the two resulting electrode array designs are depicted in FIGS. 5A-5B. As shown, FIG. 5A provides a 2×2 electrode array in which the electrodes are comb-configuration, interdigitated electrodes. FIG. 5B provides a 2×2 electrode array in which the electrodes are spiral-configuration, interdigitated electrodes.

Electrode Array Design

The electrode from FIGS. 4A and 4E were configured in the alternating 2×2 pattern shown in FIG. 5, thus differing from that depicted in FIG. 2, which is closely packed with electrodes. These electrode geometries were chosen for experimental validation (though without being bound to any particular theory) as the geometries are fundamentally different. The sparse 2×2 pattern was chosen in this particular case (1) to facilitate trace routing, (2) enhance material handling, and (3) allow for more selective pick-and-place operations. Such checkerboard-like patterns are useful, as electromechanical systems can at times require interspersed objects to aid in cooling, as seen in the insect-like robot in FIG. 1. Interspersed electrode placement can also be useful for desensitizing the LA process to object imperfections. To achieve 100% infill, checkerboard style systems can perform multiple pick-and-place operations per layer. Checkerboard patters, however, are not the exclusive configuration for electrodes, and are used as illustrative only.

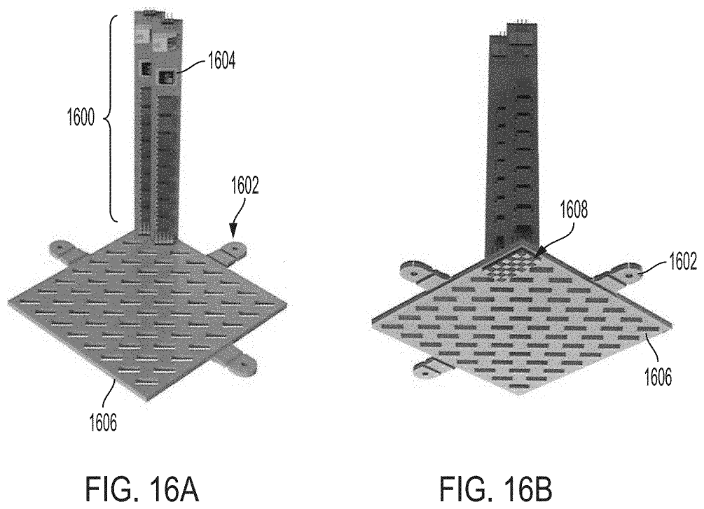

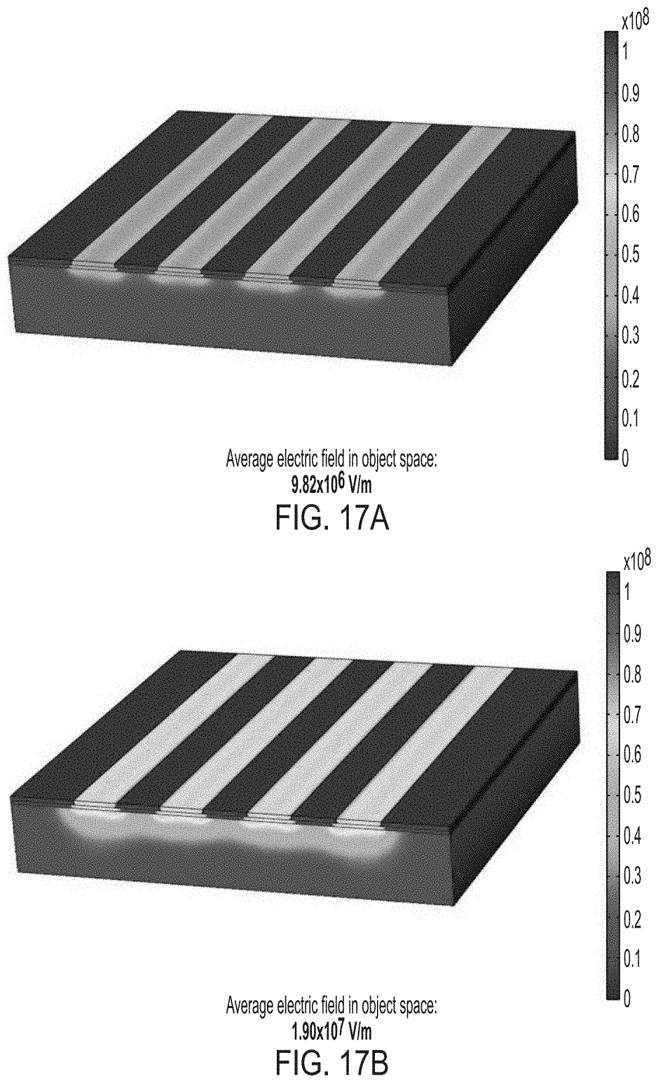

Another illustrative embodiment is shown in FIG. 16A and FIG. 16B. As shown (and as described in additional detail elsewhere herein), electroadhesors and their respective control boards can be arranged in a modular architecture to allow for the generation of arbitrary arrangements of electroadhesor geometry.

Analysis

Finite element analysis was performed in a COMSOL Multiphysics simulation environment for six unique single electrodes (FIGS. 4A-4F) and the two 2×2 electrode arrays shown in FIGS. 5A and 5B). Six single electrode geometries were considered as is shown in FIGS. 4A-4F. For each simulation the average electric field was calculated at the face of the electrode traces, representative of the location where it would contact an intended object. Analysis results of single electrodes informed the design, selection and manufacturing of the 2×2 electrode array.

Single Electrode Analysis

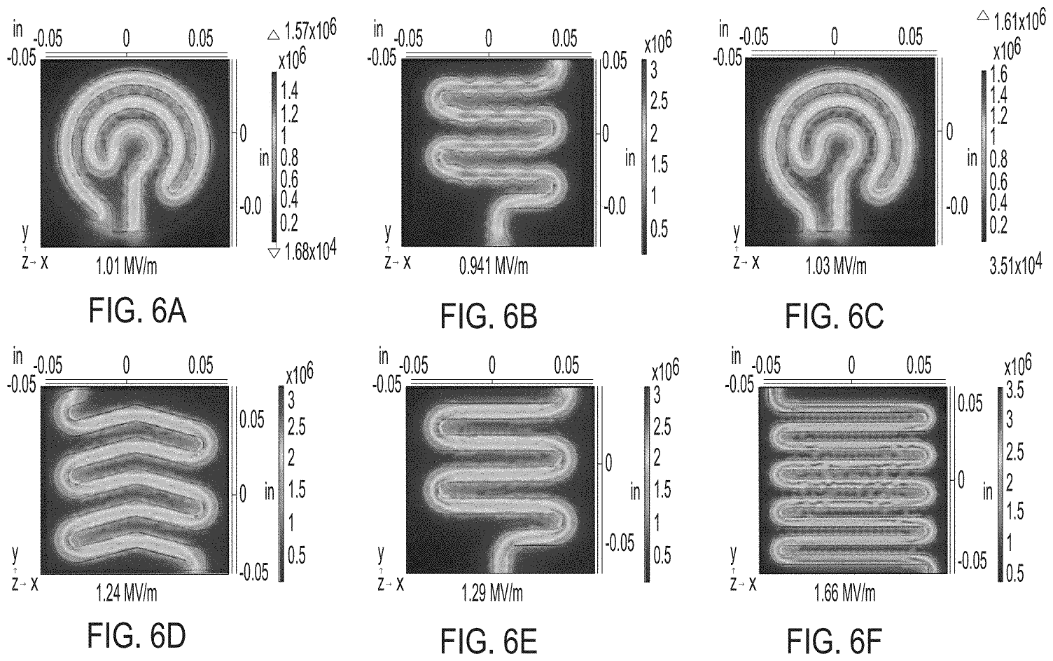

FIGS. 6A-6F provide (with FIG. 6A corresponding to FIG. 4A, FIG. 6B corresponding to FIG. 4B, FIG. 6C corresponding to FIG. 4C, FIG. 6D corresponding to FIG. 4D, FIG. 6E corresponding to FIG. 4E, and FIG. 6F corresponding to FIG. 4F) COMSOL simulations of electrostatic fields corresponding to FIGS. 4A-4F. As an example, the comb shaped electrode with 0.006″ trace spacing performed well, corresponding to an average electric field of 1.66 MV/m as seen in FIG. 6F. One can, without being bound to any theory, attribute this performance to comparatively high interdigitation length, and closely spaced traces.

Analysis of Electrode Array

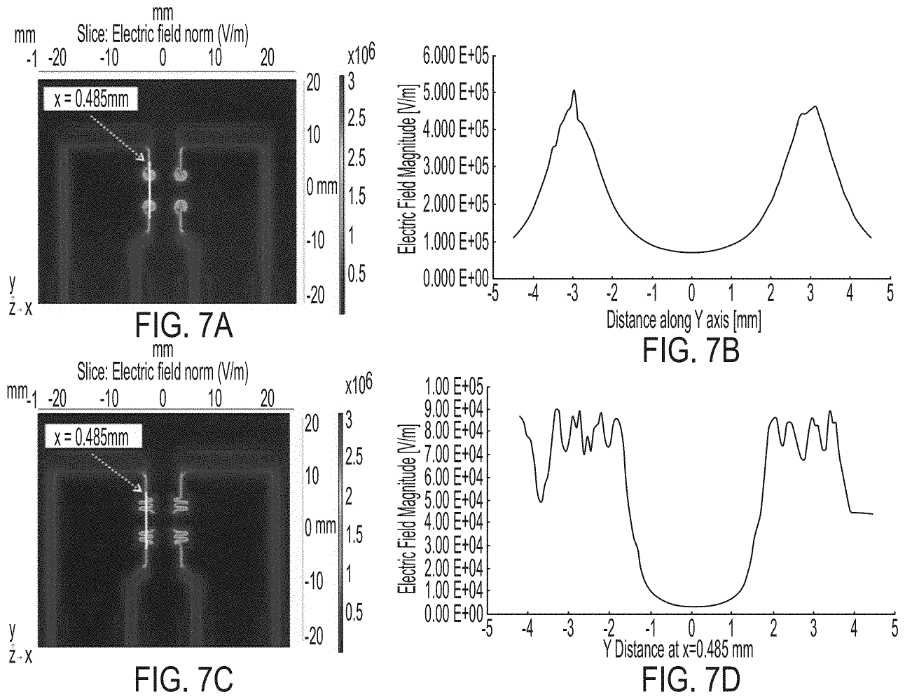

While the single electrode simulations informed electrode geometry selection for optimal electric field strength, the simulation for the 2×2 electrode arrays shows the selective capabilities of the array. To quantify the electric field decay outside of the active electrode area, the electric field was averaged at a central cross section of the electrode array. The plots of these cross sections are shown in FIGS. 7B and 7D, respectively.

The electric field of inactive areas adjacent to the square comb electrode traces is 86% lower, whereas for the spiral electrode it is 68% lower. Moreover, when comparing FIG. 7B to 7D, one can see the electric field of the comb electrode is more constant over the active electrode area. Without being bound to any particular theory, this may explain why the comb shaped electrodes exhibit particular success with grasping objects at large misalignments.

Electrode Manufacturing

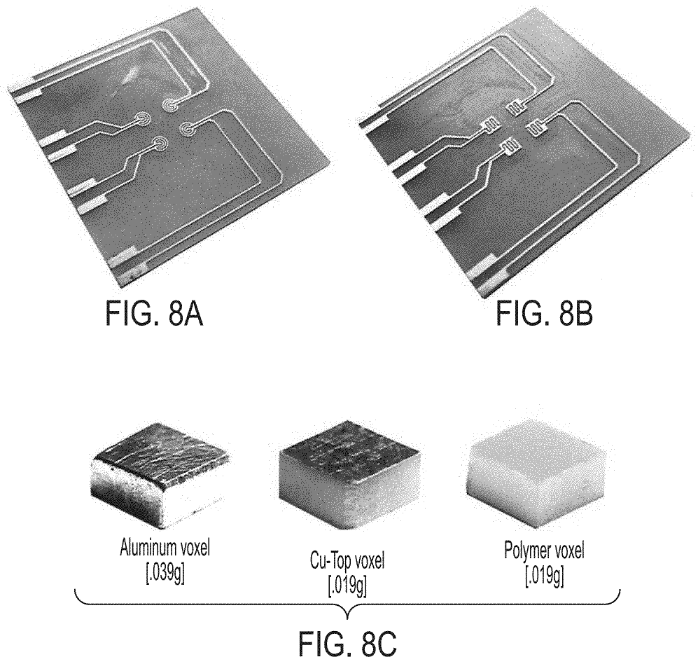

Electrodes utilized in the present study were manufactured on a desktop CNC mill (OtherMill Pro) using endmill diameters ranging from 0.010″ to 0.125″. To optimize the surface finish of electrode traces, finishing passes were employed. Additionally, an on-board vacuum fitting was used to assist with in situ chip removal. Electrodes were fabricated from single-sided FR1 boards. Following milling, electrodes were tested for continuity between traces. The as-manufactured electrodes are depicted in FIGS. 8A and 8B, while the 3×3 mm objects used in the study are shown in FIG. 8C.

Testing

Maximum Allowable Voltage

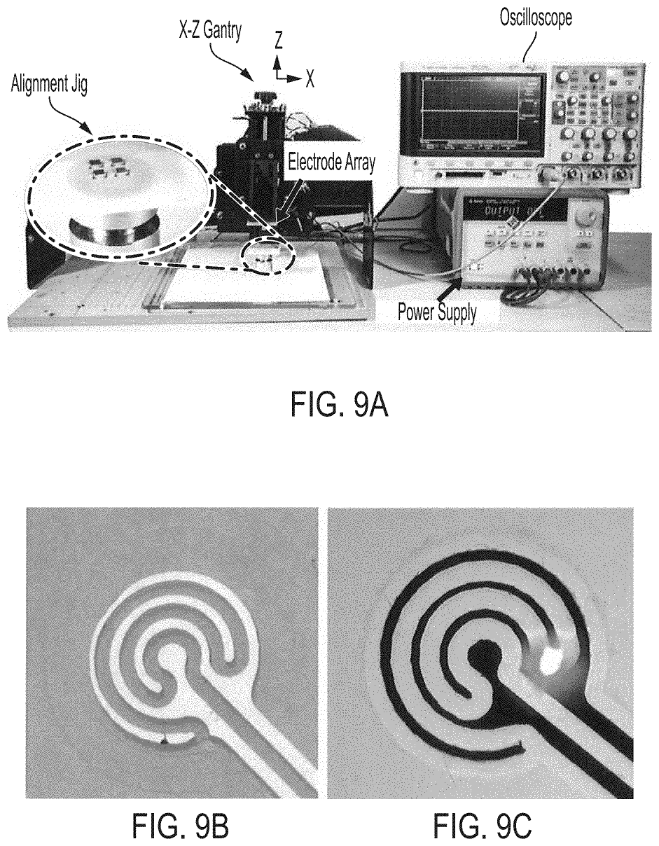

Electrode arrays were tested to failure by gradually increasing the applied voltage. Failure was defined as the voltage at which arcing occurs and the electrode loses its gripping capability. While electrodes with poorer surface finish were more susceptible to arcing at lower voltages, arcing occurred at 900-1200 V, regardless of electrode type. As shown in FIG. 9C, arcing occurred in areas of high curvature change, such as the electrode tips.

Testing Setup

As shown in FIG. 9A, electrode arrays were connected to a high voltage transformer (Sunkee # CECOMINODOO 5509) powered by an Agilent E3631A Triple Output Power Supply. High voltage was measured by a Keysight 10076C High Voltage Probe. The electrode board was then secured to the gantry of an X-carve CNC system capable of 75 μm axial precision. The electrode board was attached to the gantry using compressible 2 mm thick VHB 3M tape. By allowing the electrode array some degree of movement, the compressible tape desensitized the system to ±2° tip/tilt misalignment errors, while also ensuring that each object achieves flush contact with its respective electrode leads.

To ensure adequate alignment in the x-y plane, an alignment jig, also depicted in FIG. 9A, was machined. The jig is equipped with two reference surfaces to help locate the objects with respect to the electrodes. To achieve this objective, the reference surfaces were manually placed at tangent to the electrode board prior to each trial.

As shown in the figure, the white bracket of the jig is positioned on two layers of 1 mm thick neoprene foam to allow independent vertical movement of objects. This movement maximizes surface-to-surface contact between objects and electrodes and further desensitizes the system to tolerance stack-ups between the electrode array and objects. The objects used in electrode array trials conducted as a part of this investigation are shown in FIG. 8C, which depicts (1) a polymeric object, (2) polymeric object with a metal top, and (3) an aluminum object.

Testing Procedure

Electrode arrays were covered with Teflon™ tape to enable the adhesion of conducting objects. Each trial consisted of 20 attempts of simultaneously picking up four objects from the jig. The steps involved in the testing procedure are presented in Table 2.

TABLE 2
Reliability testing procedure adopted
for 2 × 2 electrostatic grippers.

| | |
|---|---|
| 1. | Randomly position four objects on the alignment jig |
| 2. | Align the jig with the electrode |
| 3. | Apply voltage [e.g., 75-800 V] |
| 4. | Move gantry down to apply 3 N of normal force to objects at |
| | an approach speed of 100 mm/min |
| 5. | Dwell for 1.0 s |
| 6. | Move gantry up at 200 mm/min to the final height of 8 mm |
| 7. | Count the successfully grasped objects |
| 8. | Turn off the voltage supply |

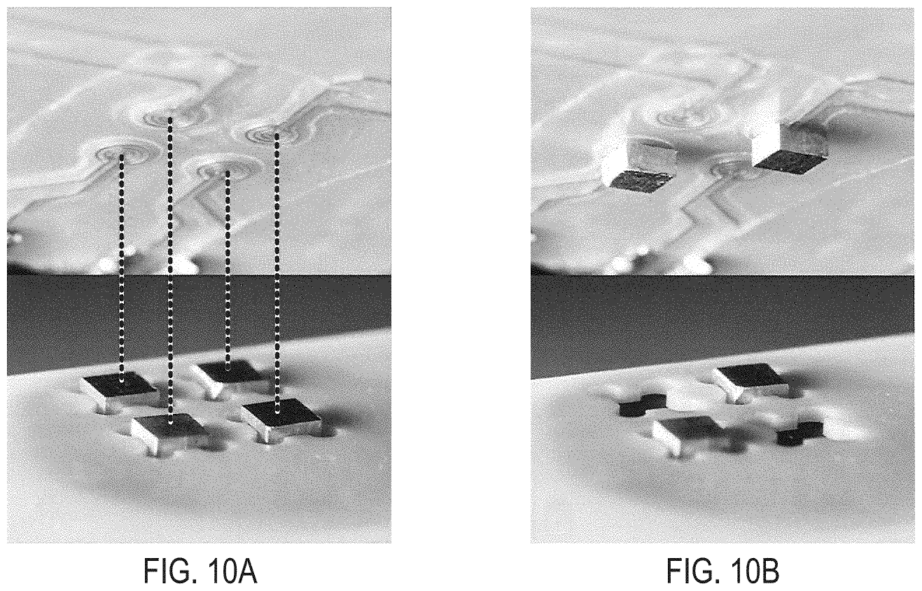

At the beginning and end of each trial, dry runs were performed to check for false positive pickup, which occurred when using masking tape as the dielectric medium. The issue of false positives was mitigated by using Teflon tape with a silicone adhesive. After each pickup attempt, the collected objects were taken out of the jig and randomly replaced to simulate the machine encountering a new layer of objects in a LA process. Four objects on the alignment jig are shown in FIG. 10A, which figure also shows the alignment between the electrodes and the objects. FIG. 10B shows a pickup operation in which only two of the electrodes were activated such that only those objects in register with those activated electrodes were collected.

Results

Gripping Reliability Tests

Gripping reliability was one aspect studied. In the context of the current investigation, reliability was defined as the ratio of collected objects to the number of attempted pickups. Specifically, a pickup was deemed successful when an object is gripped for 1 second or longer at a height of 8 mm above the object jig.

Centered Objects

The gripping reliability of objects that were centered to their respective electrodes is shown in FIG. 9A. These trials represent nominal testing conditions, in which the electrodes are aligned to +/−0.1 mm of their intended object. As can be seen from the graph, spiral electrodes outperformed comb electrodes at lower voltages, and asymptotically approached 100% gripping reliability at 300 V. However, when electrodes were covered with a dielectric (Teflon™ tape), comb electrode arrays outperformed the spiral electrode arrays. A dielectric-covered array can be used; arrays can be configured to work with both conductive and non-conductive materials.

Misaligned Objects

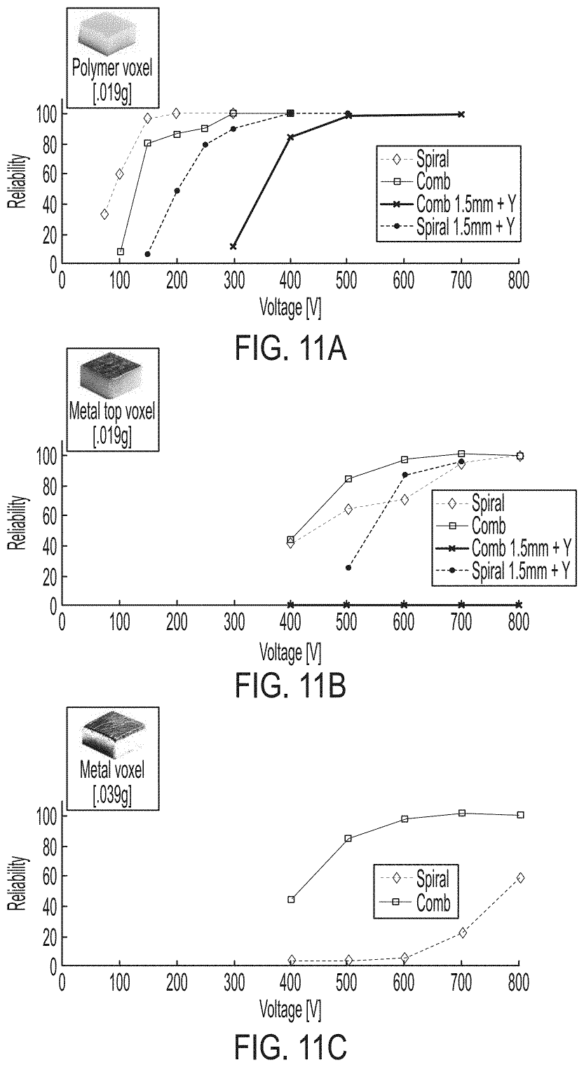

Also tested was gripping reliability at 50% object-electrode misalignment in the y-axis direction and the results are reported in FIGS. 11A and 11B. Such misalignment was intentionally chosen to explore the possibility of the electrode arrays gripping objects or parts that are of a relatively bigger size, or uneven integer multiples of the checkerboard-style spacing. As can be seen from the graphs, the performance of comb electrodes was improved (in some configurations) relative to that that of spiral electrodes.

Electrodes and Voltage Ranges

Electrodes with a dielectric (e.g., Teflon™ tape) showed strong performance. Voltage for effective and reliable multi-material gripping can be in a variety of ranges, e.g., 600-800 V range.

Part Building

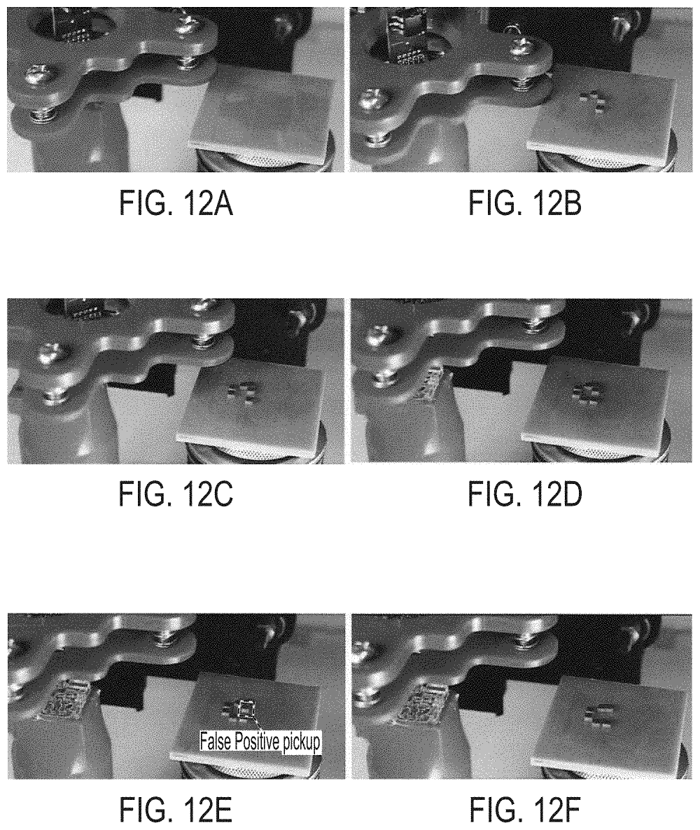

To demonstrate the additive manufacturing capabilities of Layered Assembly, a discretized letter “C” was manufactured out of copper-topped objects as seen in FIGS. 12A-12F. FIG. 12A illustrates the beginning of the processes, with an empty tray in pink, and a blue deposition head. FIG. 12B illustrates the completed placement of first batch of objects. FIG. 12C illustrates the completed placement of the second batch of objects. FIG. 12D illustrates the completed placement of third batch of objects. FIG. 12E illustrates the recognition of an extraneous object (a “false positive” pickup), which object was noticed and removed, leaving (FIG. 12F) the final discretized “C” arrangement of objects, which final “C” is the result of three separate pick and place operations. After all objects were placed on the build tray, the objects were sprayed with an acrylic coating to bond them together. The disclosed technology is, of course, not limited to acrylic coating, and the coating can be changed to match the user's desired form and function.

Component Grasping

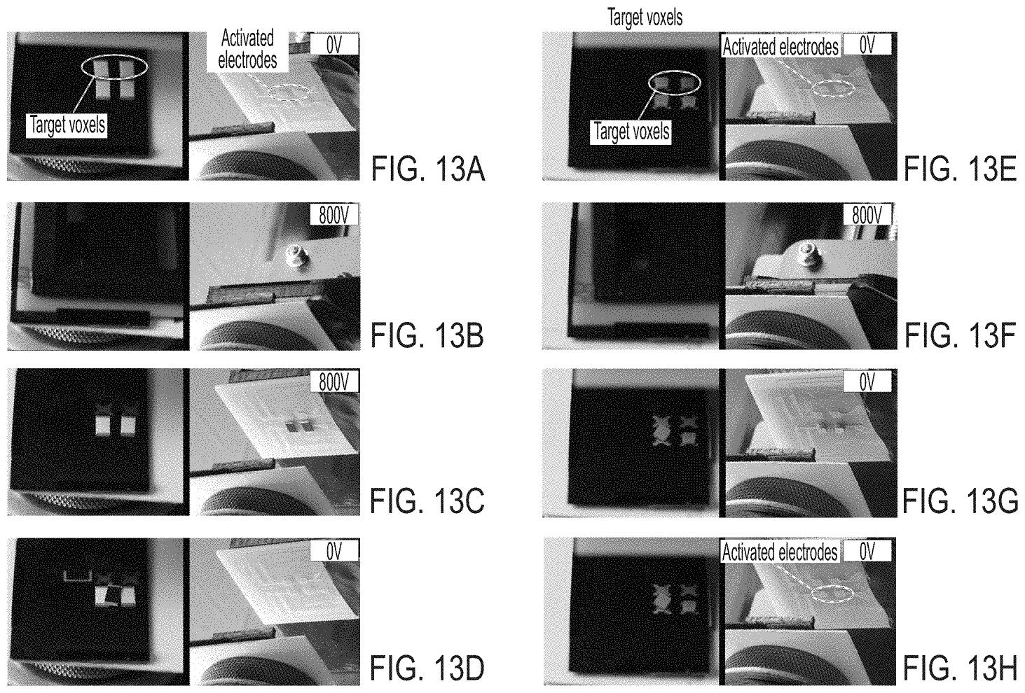

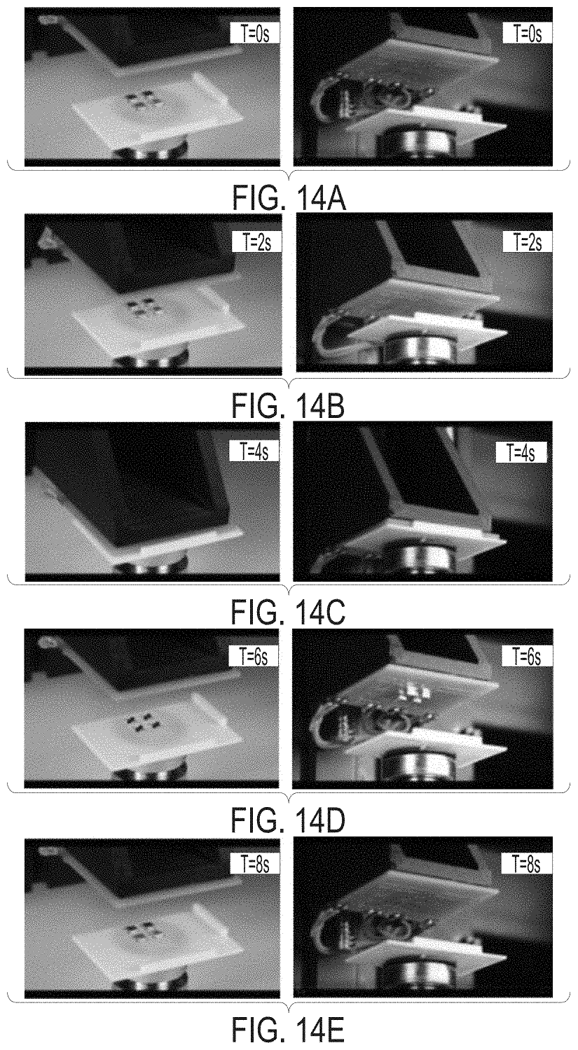

In addition to the discretized letter “C”, also explored was the capability of electrode arrays to grasp commercially available components such as the surface-mounted resistors shown in FIGS. 13A-13H, which FIGS. illustrate an exemplary fabrication process.

FIG. 13A shows (left panel) a view of a 2×2 supply of SMT resistor objects (the “target voxels” intended to be picked up are circled) disposed on a support, and the figure also shows (right panel) a view of the electrode array (at 0V, with circling to show the electrodes that will be activated) to be brought into engagement with the objects. FIG. 13B provides (left panel) a view of the electrode array lowered such that the electrodes are superposed over the objects to be picked up and shows (right panel) a view of the electrode array (at 800V) superposed over the objects. FIG. 13C provides (left panel) a view of the object supply, showing the absence (with X's) of the target objects, which objects have been picked up by the activated electrodes of the electrode array.

The right panel of FIG. 13C shows the electrode array (at 800V), with the two target objects adhered to the electrodes that were in register with those target objects. FIG. 13D provides (left panel) a view of the object supply after the voltage to the array has been turned off, showing that the two target objects have been released from the array and have fallen back down. The right panel of FIG. 13D shows the array at 0V, at which voltage the previously-adhered objects are no longer adhered.

FIG. 13E illustrates (left panel) a supply of polymer objects for adhesion, with the target objects being circled. The right panel of FIG. 13E illustrates the electrode array (at 0V), with circling used to show the electrodes that will be activated. FIG. 13F illustrates (left panel) the electrode array superposed over the supply of objects, and also illustrates (right panel) the electrode array (at 800V) superposed over the objects.

FIG. 13G illustrates (left panel) the object supply after engagement with the electrode array, showing the absence of the voxels that have been adhered to the array. FIG. 13G also illustrates (right panel) the electrode array (at 0V) with the target voxels adhered thereto. When voltage is turned off, there can be a delay (e.g., 0.01 seconds or greater) during which electroadhesion is still present, as illustrated in FIG. 13G, which FIG. shows electrostatic attraction at 0 V. FIG. 13H illustrates (left panel) objects that remain in their original location (and were not picked up), and (right panel) the set of electrodes after the voltage is turned off, illustrating that no objects remain adhered to the electrode set.

FIGS. 14A-14E provide screenshots from a video recording showing an exemplary electrostatic pickup of aluminum objects. FIG. 14A shows (left panel), a supply of four (aluminum) objects, and FIG. 14A also shows (right panel) an electrode array at 800V. FIG. 14B shows (left panel) the electrode array (at 800V) approaching the supply of objects, and the right panel of FIG. 14B shows the electrode array approaching the supply of objects, from another angle.

FIG. 14C shows (left panel) the electrode array (at 800V) superposed over the supply of objects. FIG. 14C shows (right panel), the electrode array superposed over the supply of objects, from another angle. FIG. 14D shows (left panel) the absence of the aluminum objects after the objects were adhered to the array, and also shows (right panel) a view of the four aluminum objects adhered to the array (at 800V). FIG. 14E shows (left panel) the aluminum objects following their release from the array after the voltage to the array is reduced to 0V, and also shows (right panel) the array (at 0V) with no aluminum objects adhered thereto.

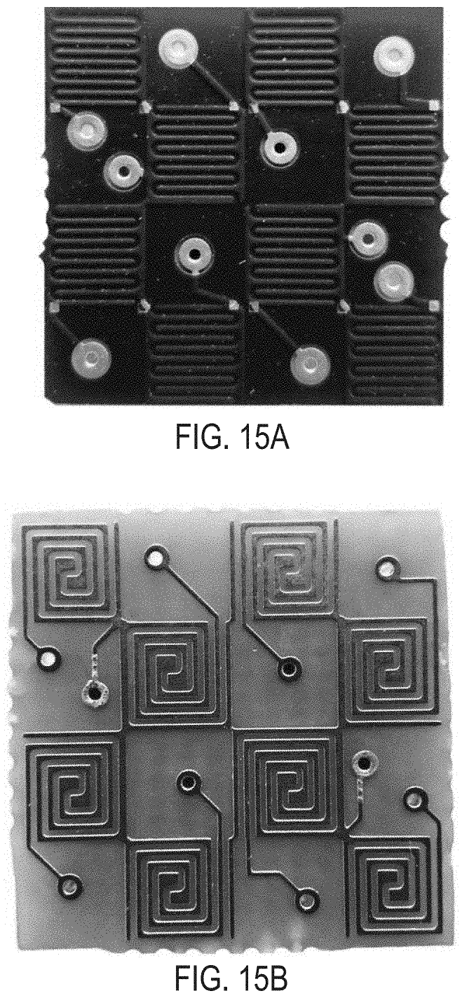

FIG. 15A and FIG. 15B provide magnified views of an exemplary array of electrodes; as shown, the electrodes are tiled in an alternating fashion so as to form a 4×4 array, with every other space filled in by an electrode so as to give rise to 8 electrodes within a 4×4 matrix. (The circular elements are vias, which vias serve to connect the electrodes to voltage sources, controllers, and other modalities.)

It should be understood that individual electrodes on a given substrate can themselves be individually addressable. For example, each of the 8 electrodes on the substrate in FIG. 15A can be individually addressable. Further, individual substrates can themselves be individually addressable. For example, a first substrate can have 10 electrodes disposed thereon in a checkerboard pattern, and a second substrate can have 10 electrodes disposed thereon in a checkerboard pattern. The electrodes of the first substrate can be individually addressed, and the electrodes of the second substrate can also be individually addressed; likewise the first substrate (in general) can be individually addressed separately from the second substrate. In this way, the user has 20 individually addressable electrodes, the electrodes themselves being disposed on two independently addressable substrates.

FIGS. 16A-16B provide views of an example embodiment of the disclosed technology. As shown, an assembly can include a jig 1606, which jig can also be termed a frame, an aligner, or a substrate. The jig serves as a mount for electrodes and related control modules, and a jig can include one or more openings (e.g., in slot form) extended therethrough. Jig 1606 can include one or more mounting flanges 1602, which flanges can be used to secure the jig to an armature, a stage, or other modality. As shown in FIG. 16A, a controller 1604 can be mounted on the jig, with the connections of the controller extending through an opening formed in the jig so as to connect with an electrode (not shown in FIG. 16A) disposed on the other side of the jig. FIG. 16B provides a view of the bottom of jig 1606, with electrodes 1608 positioned within jig 1606 and being connected with controller 1604.

The arrangement shown in FIGS. 16A-16B thus allows for a modular, flexible, and scalable approach to LA. Jig 1606 can be used to maintain the position of one, two, or more electrodes, which electrodes can be assembled (using the jig) into a particular configuration, e.g., a 4×4 matrix. Owing to the modular nature of the jig arrangement, the electrodes can also be reassembled into an alternative arrangement, e.g., a 2×8 matrix, or even an arrangement having a single electrode at each of the four corners of the jig, with a 2×2 arrangement of electrodes at the center/middle of the jig. An electrode's controller (and/or power source; a controller and power source can be integrated into a single board or other assembly) can be mated to the jig (e.g., as shown in FIG. 16B, which shows an electrode and its controller connected together through an opening in the jig, but can also be placed at a distance from the electrode (and jig) and connected to the electrode via a connector, such as a wire, cable, or other connector. A jig can be planar, and a jig can also be rigid. This is not a requirement, however, as a jig can be curved or otherwise non-planar, and can also be formed of a flexible material so as to be conformable to a supply of objects that will be adhered to the electrodes.

Discussion

Both comb- and spiral-style electrodes perform well, and other electrode configurations are also suitable. The examples provided herein show that the electrode arrays are well adapted to picking up arbitrary cross-sections, thereby showing their use in pick-and-place applications.

A number of additional variations can be employed. One can increase electrode flatness, thereby increasing the surface-to-surface contact between electrode and object. This can be achieved by, e.g., adding fillers between electrode traces, allowing for more uniform contact between the dielectric strip and the electrode surface. One can also utilize both manual and automated visual feedback to diagnose mishandled objects. A system can also be used as a high-resolution electrostatic sensor. In such a sensor, electrodes can be used to monitor voltage information in one or more modalities, e.g., voltage, capacitance, current.

Summary

A Boeing 747™ airplane is comprised of over six million parts, assembled by a custom manufacturing system, and relies on an intricate global supply chain involving 1500+ companies. This and other assembly applications can be performed efficiently by the disclosed Layered Assembly with electroadhesive grippers, as they are inherently solid-state, relatively low-power grippers that parallelize well for N x. N and other arrays. The present disclosure demonstrates that electroadhesion is a viable method of astrictive prehension for the selectively parallel, multi-material gripping necessary for Layered Assembly.

### Example Embodiments

The following embodiments are exemplary only and do not limit the scope of the present disclosure or of the appended claims.

### Embodiment 1

A positioner system, comprising: one or more (e.g., a plurality of) electroadhesive elements, an electroadhesive element comprising a first electrode and a second electrode, an electroadhesive element being configured to effect electroadhesion between the electroadhesive element and an object, and the electroadhesion of one or more of the one or more electroadhesive elements optionally being independently controllable.

An electrode (or group of electrodes) can be controlled by an independently addressable controller. As one example, in an N×N array of electroadhesive elements, two electroadhesive elements of the array can be independently controlled. In an N×N array of electroadhesive elements, single elements can be indpendently controlled.

As described elsewhere herein, a variety of objects (also termed “voxels”) can be used. Some non-limiting examples include: hard polymers, soft polymers, metallic objects (i.e., objects that comprise a metal portion), sheet (e.g., laminate or tape), dissolvable objects (for support structure), electroactive, memory/RAM objects, microprocessor objects, solder objects, epoxy objects, solder mask objects, elastic, ceramic, composite, phase changing, recyclable, photovoltaic, light-emitting, thermo-active, thermo-optic, sensing, thermo-electric, piezo-electric, power storing, resistive, inductive, logic, self-aligning, anisotropic, auxetic, shape memory, edible objects, objects manufactured from recycled, remanufactured, or repurposed material, transistors of various shapes, and others. Because electroadhesion is effective on essentially any material, the choice of objects that can be manipulated using the disclosed technology is virtually unlimited.

### Embodiment 2

The positioner system of Embodiment 1, wherein the electroadhesive elements are configured as an array. An array can be a so-called square array, such as 2×2, 3×3, 4×4, and so on. An array can also be a rectangular array, in which the number of rows of elements differs from the number of columns. It should be understood that electroadhesive elements can be arrayed in a periodic fashion, but this is not a requirement, as electroadhesive elements can be placed in a non-periodic fashion. Electroadhesive elements can be placed in virtually any fashion or arrangement, depending on the needs of the user.

### Embodiment 3

The positioner system of any of Embodiments 1-2, wherein an electroadhesive element comprises a dielectric material. The dielectric material can be disposed so as to be between one or both of the electrodes and a surface of the element that contacts an object. The dielectric material can be disposed so as to surmount some or all of one or both of the first electrode and the second electrode. It should be understood that an electroadhesive element can include one, two, three, four, or more different dielectric materials. Dielectric materials can be selected and positioned so as to enhance electric field strength in the object being picked up, and/or prevent dielectric breakdown.

As described elsewhere herein, a dielectric material (and/or an electrode) can also include one or more surface features, such as, e.g., pillars, ridges, points, mesas, grooves, and the like. A dielectric material (and/or an electrode) can define a root mean square height in the range of, e.g., about 1 to about 10 micrometers. The root mean square height can be 5 micrometers, or greater. The dielectric material can include one or more materials incorporated therein, e.g., nanoparticles, nanodiamonds, and the like.

### Embodiment 4

The positioner system of any of Embodiments 1-3, wherein the one or more electroadhesive elements are integrated into a substrate. A substrate (which can also be termed a “jig”) can be rigid, e.g., but can also be flexible. A substrate can be selected so that it conforms to at least a portion of an object, e.g., a spherical or ovoid object. As but one example, a substrate can be a flexible/bendable cap, similar to an EEG cap.

The electroadhesive elements can be removably integrated into the substrate, e.g., such that one or more electroadhesive elements can be manually removed from the substrate/jig. The electroadhesive elements can also be irremovably integrated into the substrate, e.g., such that such elements are physically integrated into the substrate/jig. As but one example, the material (e.g., a polymer) of the jig can be cured or otherwise formed about the electroadhesive elements.

An exemplary jig is shown in FIGS. 16A-16B, which figures are described elsewhere herein. As shown (and as explained elsewhere herein), a jig can include one or more mounting features (e.g., openings formed therethrough, tabs, slots, sockets, latches, and the like) with which an electroadhesive element can engage so as to maintain the electroadhesive element in position. The controller (and/or power source) for a given electrode can also engage (removably or irremovably) with the jig, e.g., via a mounting feature.

As explained elsewhere herein, an electrode and the electrode's respective controller can both be engaged with the jig (e.g., the controller and the corresponding electrode can both be attached to the same jig), but this is not a requirement, as an electrode can be engaged with a jig while the controller of the electrode is at a distance from the electrode and is not necessarily engaged with the same jig with which the electrode is engaged. In such an embodiment, the controller (and/or power source) of the electrode is connected via a wire, cable, or other connector system.

### Embodiment 5

The positioner system of Embodiment 4, wherein the jig (or substrate) is planar. Plates, panels, and the like are all suitable substrate conformations.

### Embodiment 6

The positioner system of Embodiment 4, wherein the jig (or substrate) defines a curvature, e.g., a cylinder or a sphere. A substrate can define a flat region and a curved region, e.g., a cylinder that is hexagonal or octagonal in cross-section. A curve can be, e.g., convex in curvature or concave in curvature.

### Embodiment 7

The positioner system of Embodiment 4, wherein the jig or substrate is capable of two or more configurations. For example, a substrate can be capable of one, two, three, or more different three-dimensional configurations. As but some examples, a substrate can be foldable, bendable, hinged, rotatable, or otherwise manipulable.

### Embodiment 8

The positioner system of any one of Embodiments 1-7, wherein at least one of the first electrode and the second electrode defines a comb, a spiral, or any combination thereof. Comb-shaped electrodes are considered especially suitable, although other electrode shapes can of course be used. Interdigitated comb electrodes (e.g., where the “teeth” of the first electrode comb are interdigitated with the “teeth” of the second electrode “comb”) are considered especially suitable. Other interdigitated configurations are considered suitable, as shown elsewhere herein.

### Embodiment 9

The positioner system of any one of Embodiments 1-7, wherein a line drawn across an electroadhesive element crosses one or both of the first and second electrodes at least once.

### Embodiment 10

The positioner system of Embodiment 9, wherein a line drawn across an electroadhesive element crosses one or both of the first and second electrodes at least twice.

### Embodiment 11

The positioner system of any one of Embodiments 4-10, wherein the system is configured to effect relative motion between the substrate and an object that is electroadhered to an electroadhesive element. Relative motion can be, e.g., motion of an electroadhesive element toward or away from the object. Relative motion can also be, e.g., motion of the object toward or away from the electroadhesive element. This can be accomplished by, e.g., having a tray on which the object is (or was) disposed move in a direction away from the electroadhesive element.

### Embodiment 12

The positioner system of any one of Embodiments 4-12, further comprising an object supply element configured to present one or more objects to the one or more electroadhesive elements. An object supply element can be, e.g., a tray, a bin, a shelf, a compartment, and the like. A supply element can comprise multiple locations (e.g., compartments) into which multiple objects are presented simultaneously. As one example, a tray can present four different compartments (similar to a bento box), each of which compartments presents a different object.

### Embodiment 13

The positioner system of Embodiment 12, further comprising a feeder element configured to deliver one or more objects to the object supply element. A feeder element can be, e.g., a conveyor, a magazine (such as a magazine that advances an object to a location after a previous object has been removed from that pickup location, similar to a Pez™ dispenser or ammunition clip/magazine). Other exemplary feeder elements include (without limitation), a vibrating tray feeder (e.g., one that uses controlled vibration to encourage objects into particular locations), a conveyor belt feeder that replaces empty objects, and a spray feeder where objects are sprayed out of a nozzle.

### Embodiment 14

The positioner system of Embodiment 13, wherein the feeder element is configured to advance one or more objects to the object supply element. As one non-limiting example, a Pez™ dispenser-style such element can be used.

### Embodiment 15

The positioner system of any one of Embodiments 12-14, wherein the system is configured to position at least one electroadhesion element into register with an object presented by the object supply element. This can be accomplished by having the system configured such that a N×N array of electroadhesive elements is disposed above an object supply element (e.g., a tray) that provides an N×N array of objects. A system can be configured to adjust a position of an electroadhesive element, an object, or both, relative to one another. The adjustment can be performed in a manual or automated fashion.

A system can also be configured to effect relative motion between one or more electroadhesive elements and one or more objects so as to place an object into register with an electroadhesive element. It should be understood that “in register” can mean that the entirety of an electroadhesive element is superposed over an object (or vice versa).

It should be understood that an electroadhesive element need not be in perfect register with an object so as to effect electroadhesion between the element and the object, as the disclosed technology enables operation with some or all of an electroadhesive element being superosed over some or all of an object. As an example, a portion of an electroadhesive element that is 2 cm×2 cm can be superposed over a portion of an object that is 10 cm×10 cm, and the electroadhesive element can still effect sufficient electroadhesion between itself and the object to move the object.

### Embodiment 16

The positioner system of any one of Embodiments 12-15, wherein the system is configured to effect electroadhesion between one or more electroadhesion elements and fewer than all objects presented by the object supply element. As an example, the system can effect electroadhesion between 3 of 9 electroadhesive elements and 3 of 9 objects that are presented to the electroadhesive elements. A system can be configured to “turn on” only certain electroadhesive elements to as to pick up objects in only a particular pattern, e.g., to pick up a circle of objects from a field of 1000×1000 objects.

### Embodiment 17

The positioner system of any one of Embodiments 12-16, wherein one or more electroadhesion elements is configured to provide a signal. Exemplary signals include capacitance, and voltage potential, as well as current can also be detected. Machine vision can also be employed. An electroadhesive element can include an imager, e.g., a camera, a photomultiplier tube, and the like, any of which can be used to determine the presence, absence, or presence of an object proximate to the electroadhesive element. The imager can in turn be used in self-correct, as the imager can monitor the position of an object picked up (or placed) by the electroadhesive element.

An imager need not, however, be incorporated onto or otherwise placed on the electroadhesive element. An imager can be placed at a distance from the electroadhesive element, and can be positioned so as to monitor the placement (or pick-up) of objects by a given electroadhesive element or elements. The results from the imager (e.g., the absence of an object from a location where the object is expected) can in turn be used as part of a quality control process. For example, if an imager determines that an expected object is not present at a given location (or that the object is not properly positioned), the system can deliver the expected object to the location (if the expected object is not present) or reposition the object, if the object is at the location but not properly positioned at that location.

### Embodiment 18

The positioner system of Embodiment 17, wherein the signal is related to a characteristic of the object. Such a characteristic can be a physical characteristic, an electrical characteristic, a chemical or compositional characteristic, and the like. In this way, a user can determine what kinds of objects are adhered to (or located nearby to) electroadhesive elements. A used can also determine the location and character of objects that have been placed.

### Embodiment 19

The positioner system of any one of Embodiments 1-17, further comprising a detector configured to detect a characteristic, location, or both of an object.

### Embodiment 20

The positioner system of Embodiment 19, wherein the detector comprises an imager, a source of electromagnetic field, a voltage monitor, a current monitor, and the like. The detector can be in communication with one or more elements configured to adjust a position of an object based on information provided by the detector. Such an element can be, e.g., a pick-and-place arm that moves (or even removes) misplaced objects. A detector can be a device that monitors one or more of impedance, current draw, leakage, and other electrical characteristics so as to determine the position of (or lack of) an object. This detection can be used to detect a missed pickup of an object or even arcing. Arcing is a phenomenon which occurs when a dielectric begins to conduct electrical current. In the case of electroadhesive grippers, arcing occurs when the operating voltage of the electrodes is increased and the electric field overcomes the dielectric strength of the dielectric. Once arcing occurs, electroadhesive force is lost, and the gripper may be damaged for future use. Arcing of a spiral electrode is shown in FIG. 9C.

Detectors configured to monitor electrical characteristics are especially suitable. A non-limiting listing of such detectors includes, without limitation: ammeter, capacitance meter, distortionmeter, electricity meter, frequency counter, galvanometer, LCR meter, microwave power meter, multimeter, megohmmeter, ohmmeter, peak meter, peak programme meter, psophometer, Q meter, time-domain reflectometer, time-to-digital converter, transistor tester, tube tester, wattmeter, voltmeter, VU meter, bus analyzer, logic analyzer, network analyzer, oscilloscope, signal analyzer, spectrum analyzer, waveform monitor, vectorscope, videoscope, and the like.

A detector can also be an imager or photomultiplier tube, which can be configured to detect the presence, absence, or even location of an object before the object is picked up (e.g., determine whether a given object is properly positioned within a supply of objects), after the object is picked up (e.g., to determine whether the object is adhered to the intended electrode), and/or after the object is placed. As explained elsewhere herein, a detector can also be a current monitor, a voltage monitor, a resistance monitor, an impedence monitor, and the like.

It should be understood that the disclosed technology can be operated in a batch, semi-batch, or continuous manner. As an example, a system can include a first roller having electroadhesive elements on the outside of the first roller. The first roller then rolls over a tray filled with a first layer of transistors and picks up the desired transistors via electroadhesion between the electroadhesive elements of the roller and the desired transistors. A second roller (also with electroadhesive elements) is rolled “behind” the first roller so as to pick up a next set of transistors from the tray. (Transistors can be advanced into compartments of the tray so as to replenish the supply of transistors in the tray, in a continuous fashion.)

### Embodiment 21

A method, comprising: with a positioner system according to any of Embodiments 1-20, effecting layered assembly by way of electroadhering one or more objects to one or more electroadhesion elements.

### Embodiment 22

A method, comprising: with one or more electroadhesive elements, the one or more electroadhesive elements optionally being arranged in an array; effecting electroadhesion between at least of the one electroadhesive elements and at least one object placed at an original location; and effecting relative motion between the object and the original location.

### Embodiment 23

The method of Embodiment 22, further comprising advancing one or more objects to an object supply element for presentation to at least one of the one or more of electroadhesive elements.

### Embodiment 24

The method of any one of Embodiments 22-23, further comprising effecting selective electroadhesion between two or more electroadhesive elements and two or more objects of a plurality of objects presented to the plurality of electroadhesive elements.

### Embodiment 25

The method of Embodiment 24, wherein the two or more objects differ from one another in at least one characteristic. Such characteristics include, e.g., size, material composition, and the like. The objects can differ from one another in one or more electrical characteristics, e.g., resistance, capacitance, and the like.

### Embodiment 26

The method of any one of Embodiments 22-25, further comprising effecting selective electroadhesion between one or more electroadhesive elements and fewer than all objects presented to the one or more electroadhesive elements. Without being bound to any particular theory, this provides an ability to pick up arbitrary shapes beyond those of objects, by turning on arbitrary arrangements of electroadhesive elements (and/or electrodes) as desired.

### Embodiment 27

The method of any one of Embodiments 22-26, further comprising detecting a location, orientation, or other characteristic of an object that, by way of electroadhesion to an electroadhesive element, undergoes motion relative to an original location of the object.

### Embodiment 28

The method of Embodiment 27, further comprising altering a location, orientation, or other characteristic of an object that, by way of electroadhesion to an electroadhesive element, undergoes motion relative to an original location of the object.

### Embodiment 29

The method of any one of Embodiments 22-28, wherein the relative motion comprises motion of the at least one electroadhesive element.

### Embodiment 30

The method of any one of Embodiments 22-29, wherein the relative motion is performed so as to effect layered assembly of a plurality of objects. As described elsewhere herein, layered assembly can comprise formation of layers that comprise one, two, or more object types.

### Embodiment 31

The method of any one of Embodiments 22-30, wherein the at least one objects is configured to effect attraction to another object. This can be characterized in some embodiments as picking up “sticky” objects, which “sticky” objects can be understood as objects which act as electrodes themselves, enabling the pickup of more than just one object per electrode. Put another way, the disclosed technology includes object-to-object interactions.

A system can effect object-to-object adhesion via, e.g., laser welding, laser soldering, polymer adhesion, chemoadhesion, friction, stir welding, mechanical interference, mechanical interlocking between objects, baking, or even adhesion between objects wherein objects act as a glue between other objects. One can apply a varying (e.g., oscillating, increasing, decreasing) current/voltage with the electroadhesive element so to modulate object adhesion and/or detachment.

### Embodiment 32

The method of any one of Embodiments 22-31, further comprising application of an electromagnetic field, the electromagnetic field optionally applied so as to effect (i) movement of the at least one object or (ii) retention of the at least one object at a location. Thus, one can utilize an electromagnetic field used in tandem with electrostatic fields for grasping, manipulating, and even sensing object location.

### Embodiment 33

A method, comprising: with a positioner system according to any one of Embodiments 1-20, determining an electrical characteristic of one or more objects positioned proximate to one or more of the electroadhesion elements of the positioner system.

The disclosed technology can also be applied as a high resolution electrostatic sensor. In this application, electrodes are used to monitor electrical information in an object or objects being tested, e.g., voltage, capacitance, current, and the like.

As an example, a system can be configured to monitor one or more of voltage, current, and resistance at an electrode or proximate to the particular electrode. This can be accomplished by, e.g., having a monitor (e.g., a current monitor, a voltage monitor, a resistance monitor, an impedance monitor) operate in connection with an electroadhesive element. In this way, the system can determine a characteristic being monitored (e.g., voltage) and further determine (in a manual or an automated fashion) whether that characteristic being monitored is within a normal/expected range or if the characteristic is outside the expected range. For example, one might expect an electrode that engages with a particular object to exhibit a particular voltage leakage value. If the monitored voltage leakage value is not the expected value, the system can alert the user to that fact, as the difference between the observed voltage leakage and the expected voltage leakage can indicate that the object being manipulated has been misaligned, is missing, or even that the object being manipulated somehow differs (e.g., in size, in material composition) from the object that was expected.

A system can be configured to compare an observed value for a given characteristic (e.g., current) to the expected value for that characteristic, and if the observed value differs by a certain margin from the expected value, the system can alert a user and/or take one or more steps in an automated fashion. Such steps include, without limitation, repositioning the object being manipulated, discarding the object being manipulated, replacing the object being manipulated with a replacement object (e.g., an object taken from a store of spare objects), and the like. In this way, a system can be self-correcting in that the system can detect misalignments of objects being manipulated, detect defects in objects being manipulated (i.e., defects that give rise to a sufficiently different characteristic in the object than the characteristic that was expected), detect the absence of an object that is intended to be manipulated, and the like, and then take appropriate steps (replacement of the object being analyzed, realignment of the object being analyzed, and the like). The system can perform these steps in an automated fashion, as instructions for performing these steps can be placed on a computer-readable memory.

A system can also be configured to operate as a sensor, with or without also being configured to manipulate objects. As an example, a system can include one or more electroadhesive elements (e.g., as described herein) as well as one or more monitors in connection with one or more such electroadhesive elements. One or more electroadhesive elements can be placed into electrical communication (e.g., via contact) to an object, which object can then be analyzed at multiple locations (each location corresponding to an electroadhesive element) for its electrical properties at those locations.

As one non-limiting example, a set of 16 electroadhesive elements (arranged in a 4×4 matrix) could be contacted to a silicon wafer, and the resistance of the wafer could then be determined at each of the elements' locations on the wafer. In this way, the user can create a map of the wafer's resistance at 16 locations, thereby providing information concerning the uniformity of the wafer's composition—if the wafer's resistance is similar at all locations, the wafer may be of uniform composition, and if the wafer's resistance is anomalous at one or more locations, the wafer may be of non-uniform composition and can be further evaluated (or even discarded). The set of 16 electroadhesive elements can also be contacted to the wafer at a first region, the electrical properties of the wafer evaluated at that first region, and then the set of 16 electroadhesive elements can be contacted to the wafer at a second location, and the electrical properties of the wafer evaluated at that second location. In this way, one can use the disclosed technology to efficiently evaluate an object by generating a map of one or more of the object's electrical properties.

This evaluation can be, e.g., a determination of the uniformity of the one or more electrical properties across the object. The evaluation can be used to identify the object, e.g., by comparing the electrical properties of the object to the expected electrical properties of a known object. For example, one can determine the resistances across a silicon wafer that is of unknown composition, and by comparing the determined resistances to the resistances of a silicon wafers of known compositions, one can then determine the composition of the silicon wafer under study. In this way, one can compare one or more electrical properties of an object under study to the corresponding one or more electrical properties of objects from a library of such properties, and then determine the identity of the object under study based on the closest match between the object under study and the objects in the library. An array of electroadhesive elements in turn allows one to efficiently develop highly detailed property maps (i.e., with data points at many locations, which locations can be close to one another) for objects under study.

### Embodiment 34

The method of Embodiment 33, wherein the electrical characteristic is a voltage, a current, a resistance, an impedence, or any combination thereof.

### Embodiment 35

The method of any one of Embodiments 33-34, further comprising determining the electrical characteristic at two or more locations on the object.

### Embodiment 36

The method of any one of Embodiments 33-35, further comprising manipulating the object in response to the electrical characteristic.

### Embodiment 37

The method of Embodiment 36, wherein the manipulating comprises repositioning the object.

### Embodiment 38

The method of Embodiment 36, wherein the manipulating comprises discarding the object.

### Embodiment 39

The method of Embodiment 36, wherein the manipulating comprises replacing the object.

### Embodiment 40

The method of any one of Embodiments 33-35, further comprising identifying the object based on the electrical characteristic.

### Embodiment 41

An object-comprising workpiece, assembled according to the method of any one of Embodiments 22-32.

As described elsewhere herein, the disclosed technology can be used to manufacture a broad variety of devices and articles. For example, the disclosed technology can be used to assemble printed circuit boards, as well as thin film assembly, food handling, food dispensing, textile handling, space-borne gripping applications (electrostatics perform well in vacuum), and other articles that can be assembled in a layered fashion.

### REFERENCES

The following references are provided for convenience and are incorporated herein in their entireties for any and all purposes.
N. Oxman, E. Tsai, M. Firstenberg, Digital anisotropy: A variable elasticity rapid prototyping platform, Virtual Phys. Prototyp. (2012). doi:10.1080/17452759.2012.731369.
F. Stute, J. Mici, L. Chamberlain, H. Lipson, Digital Wood: 3D Internal Color Texture Mapping, 3D Print. Addit. Manuf (2018). doi:10.1089/3dp.2018.0078.
K. A. Mumtaz, N. Hopkinson, Laser melting functionally graded composition of Waspaloy® and Zirconia powders, J. Mater. Sci. 42 (2007) 7647-7656. doi:10.1007/s10853-007-1661-3.
W. Li, S. Karnati, C. Kriewall, F. Liou, J. Newkirk, K. M. Brown Taminger, W. J. Seufzer, Fabrication and characterization of a functionally graded material from Ti-6A1-4V to SS316 by laser metal deposition, Addit. Manuf 14 (2017) 95-104. doi:10.1016/J.ADDMA.2016.12.006.
B. P. Conner, G. P. Manogharan, A. N. Martof, L. M. Rodomsky, C. M. Rodomsky, D. C. Jordan, J. W. Limperos, Making sense of 3-D printing: Creating a map of additive manufacturing products and services, Addit. Manuf 1-4 (2014) 64-76. doi:10.1016/J.ADDMA.2014.08.005.
ASTM. F2792-12a. Standard Terminology for Additive Manufacturing Technologies, (2012). doi:10.1520/F2792-12A.
E. Malone, K. Rasa, D. Cohen, T. Isaacson, H. Lashley, H. Lipson, Freeform fabrication of zinc-air batteries and electromechanical assemblies, Rapid Prototyp. J. 10 (2004) 58-69. doi:10.1108/13552540410512543.
J. T. Muth, D. M. Vogt, R. L. Truby, Y. Mengtic, D. B. Kolesky, R. J. Wood, J. A. Lewis, Embedded 3D Printing of Strain Sensors within Highly Stretchable Elastomers, Adv. Mater. 26 (2014) 6307-6312. doi:10.1002/adma.201400334.
J. Hiller, H. Lipson, Design and analysis of digital materials for physical 3D voxel printing, Rapid Prototyp. J. 15 (2009) 137-149. doi:10.1108/13552540910943441.
R. MacCurdy, A. McNicoll, H. Lipson, Bitblox: Printable digital materials for electromechanical machines, Int. J. Rob. Res. 33 (2014) 1342-1360. doi:10.1177/0278364914532149.
G. A. Popescu, T. Mahale, Gershenfeld Neil A, Digital materials for digital printing, in: Int. Conf. Digit. Fabr. Technol., Denver Colo., 2006: p. 3. http://cba.mit.edu/docs/papers/06.09.digital_materials.pdf (accessed Apr. 19, 2018).
D. Dikovsky, Multi-material 3D Printing, in: RadTech—Assoc. UV EB Curing Technol., 2015: p. 14. https://www.slideshare.net/radtechuveb/multimaterial-3d-printing (accessed Apr. 24, 2018).
W. Langford, A. Ghassaei, N. Gershenfeld, Automated Assembly of Electronic Digital Materials, in: Vol. 2 Mater. Biomanufacturing; Prop. Appl. Syst. Sustain. Manuf., ASME, 2016: p. V002T01A013. doi:10.1115/MSEC2016-8627.
C. E. Owens, A. J. Hart, High-precision modular microfluidics by micromilling of interlocking injection-molded blocks, Lab Chip. 18 (2018) 890-901. doi:10.1039/C7LC00951H.
N. A. Gershenfeld, When Things Start to Think, Henry Holt, 1999.
Application system Genkotsu-Robot 2 High Speed Picking and Assembly Robot, (2015). http://www.fanucamerica.com/cmsmedia/datasheets/M-2iA Series_167.pdf (accessed Apr. 18, 2018).
G. J. Monkman, Wiley InterScience (Online service), Robot grippers, Wiley-VCH, 2007. https://www.wiley.com/en-us/Robot+Grippers-p-9783527406197 (accessed May 27, 2018).
G. Monkman, An Analysis of Astrictive Prehesion, Int. J. Rob. Res. 16 (1997).
H. Lipson, J. Hiller, C. Perich, S. Bernard, R. MacCurdy, F. Apoorva, Rapid Assemblers for Voxel-Based VLSI Robotics, 2014. http://www.dtic.mil/get-tr-doc/pdVAD=ADA624831 (accessed May 28, 2018).
C. Perich, R. MacCurdy, A. Macner, J. Mici, P. H. Steen, H. Lipson, Parallel manipulation of millimeter-scale components using electro-osmotically controlled droplet arrays, IEEE Trans. Autom. Sci. Eng. (2019).
B. C. Leung, N. R. Goeser, L. A. Miller, S. Gonzalez, Validation of electroadhesion as a docking method for spacecraft and satellite servicing, IEEE Aerosp. Conf. Proc. 2015-June (2015). doi:10.1109/AERO.2015.7119283.
J. Guo, T. Bamber, T. Hovell, M. Chamberlain, L. Justham, M. Jackson, Geometric Optimisation of Electroadhesive Actuators Based on 3D Electrostatic Simulation and its Experimental Verification, IFAC-PapersOnLine. 49 (2016) 309-315. doi:10.1016/j.ifaco1.2016.10.574.
J. Hiller, H. Lipson, Methods of parallel voxel manipulation for 3D digital printing, in: 18th Annu. Solid Free. Fabr. Symp., 2007: pp. 200-211. https://sffsymposium.engr.utexas.edu/Manuscripts/2007/2007-17-Hiller.pdf (accessed Apr. 18, 2018).
R. Batra, H. Lipson, Transforming Lunar Regolith into a Digital Printable Material, in: Sp. Resour. Roundtable Planet. Terr. Min. Sci. Symp. Seventh Jt. Meet., 2016: p. 1,2.
J. Guo, M. Tailor, T. Bamber, M. Chamberlain, L. Justham, M. Jackson, Investigation of relationship between interfacial electroadhesive force and surface texture, J. Phys. D. Appl. Phys. 49 (2016) 2. doi:10.1088/0022-3727/49/3/035303.
D. Ruffatto, J. Shah, M. Spenko, Increasing the adhesion force of electrostatic adhesives using optimized electrode geometry and a novel manufacturing process, J. Electrostat. 72 (2014) 147-155. doi:10.1016/j.elstat.2014.01.001.
G. Monkman, Electroadhesive microgrippers, Ind. Robot An Int. J. 30 (2003) 326-330. doi:10.1108/01439910310479595.
C. Cao, X. Sun, Y. Fang, Q. H. Qin, A. Yu, X. Q. Feng, Theoretical model and design of electroadhesive pad with interdigitated electrodes, Mater. Des. 89 (2016) 485-491. doi:10.1016/j.matdes.2015.09.162.
Rui Chen, Rong Liu, Hua Shen, Modeling and analysis of electric field and electrostatic adhesion force generated by interdigital electrodes for wall climbing robots, in: 2013 IEEE/RSJ Int. Conf. Intell. Robot. Syst., IEEE, 2013: pp. 2327-2332. doi: 10.1109/IROS.2013.6696682.
Inventables Inc, (n.d.). https://www.inventables.com/technologies/x-carve (accessed Apr. 18, 2018).
Cellular Machines—Creative Machines Lab—Columbia University, (n.d.). https://www.creativemachineslab.com/cellular-machines.html (accessed Jul. 17, 2018).

What is claimed:

1. A positioner system, comprising:
one or more electroadhesive elements,
an electroadhesive element comprising a first electrode and a second electrode,
an electroadhesive element being configured to effect electroadhesion between the electroadhesive element and an object, and
the electroadhesion of one or more of the one or more electroadhesive elements optionally being independently controllable.

2. The positioner system of any of claim 1, wherein an electroadhesive element comprises a dielectric material, the dielectric material optionally defining a root mean square height of from about 1 to about 10 micrometers, and the dielectric material optionally comprising one or more materials incorporated therein.

3. The positioner system of claim 1, wherein the one or more electroadhesive elements are integrated into a substrate.

4. The positioner system of claim 3, wherein the system is configured to effect relative motion between the substrate and an object that is electroadhered to an electroadhesive element.

5. The positioner system of claim 1, wherein at least one of the first electrode and the second electrode defines a comb, a spiral, or any combination thereof.

6. The positioner system of claim 1, further comprising an object supply element configured to present one or more objects to the one or more electroadhesive elements.

7. The positioner system of claim 6, wherein the system is configured to position at least one electroadhesion element into register with an object presented by the object supply element.

8. The positioner system of claim 7, wherein the system is configured to effect electroadhesion between one or more electroadhesion elements and fewer than all objects presented by the object supply element

9. The positioner system of claim 8, wherein one or more electroadhesion elements is configured to provide a signal, the signal optionally being related to a capacitance, a resistance, a voltage, or a current.

10. The positioner system of claim 1, further comprising a detector configured to detect a characteristic, location, or both of an object.

11. The positioner system of claim 10, wherein the detector comprises an imager, a source of electromagnetic field, or both.

12. A method, comprising
with one or more electroadhesive elements, the one or more electroadhesive elements optionally being arranged in an array;
effecting electroadhesion between at least of the one electroadhesive elements and at least one object placed at an original location; and
effecting relative motion between the object and the original location.

13. The method of claim 12, further comprising advancing one or more objects to an object supply element for presentation to at least one of the one or more electroadhesive elements.

14. The method of claim 12, further comprising effecting selective electroadhesion between two or more electroadhesive elements and two or more objects of a plurality of objects presented to the one or more electroadhesive elements.

15. The method of claim 14, wherein the two or more objects differ from one another in at least one characteristic.

16. The method of claim 14, further comprising effecting selective electroadhesion between one or more electroadhesive elements and fewer than all objects presented to the one or more electroadhesive elements.

17. The method of claim 12, further comprising detecting a location, orientation, or other characteristic of an object that, by way of electroadhesion to an electroadhesive element, undergoes motion relative to an original location of the object.

18. A method, comprising:
with a positioner system according to any one of claims 1-20, determining an electrical characteristic of one or more objects positioned proximate to one or more of the electroadhesion elements of the positioner system.

19. The method of claim 18, wherein the electrical characteristic is a voltage, a current, a resistance, an impedence, or any combination thereof.

20. The method of claim 18, further comprising determining the electrical characteristic at two or more locations on the object.
